(19) United States
(12) Patent Application Publication
(10) Pub. No.: US 2025/0007478 A1
(43) Pub. Date: Jan. 2, 2025

(54) WIDE-BAND JOSEPHSON PARAMETRIC AMPLIFIER

(71) Applicant: Anyon Computing Inc., Emeryville, CA (US)

(72) Inventors: Xinyu Liu, Emeryville, CA (US); Hengjiang Ren, Emeryville, CA (US); Jie Luo, Emeryville, CA (US)

(21) Appl. No.: 18/511,477

(22) Filed: Nov. 16, 2023

Related U.S. Application Data
(60) Provisional application No. 63/426,204, filed on Nov. 17, 2022.

(51) Int. Cl. H03F 7/00; H03F 19/00; H10N 60/01; H10N 60/12; H10N 60/80

(52) U.S. Cl. CPC H03F 7/00; H03F 19/00; H10N 60/0912; H10N 60/12; H10N 60/805

(57) ABSTRACT

A wide-band Josephson parametric amplifier and method of fabricating the wide-band Josephson parametric amplifier are described. The wide-band Josephson parametric amplifier comprises a substrate, a coplanar waveguide disposed on the substrate having an impedance that varies over a length of the coplanar waveguide, wherein the coplanar waveguide comprises a conductor separated from a first ground plane by a first gap and a second ground plane by a second gap, and a nonlinear resonator disposed on the substrate and coupled to the coplanar waveguide.

### CROSS-REFERENCE TO RELATED APPLICATIONS

This application claims priority to U.S. Provisional Application Ser. No. 63/426,204filed Nov. 17, 2022 entitled “Wide-Band Josephson Parametric Amplifier”. The entire contents of the foregoing application is incorporated herein by reference.

### STATEMENT OF FEDERALLY FUNDED RESEARCH

Not applicable.

### TECHNICAL FIELD OF THE INVENTION

The present invention relates in general to semiconductor processing. In particular, the present invention relates to a wide-band Josephson parametric amplifier.

### BACKGROUND OF THE INVENTION

The applications of current Josephson parametric amplifiers (JPA) in multi-qubit quantum circuits are limited because of its narrow band gain. As a result, there is a need for a wide-band Josephson parametric amplifier.

### SUMMARY OF THE INVENTION

In one embodiment of the present disclosure, a wide-band Josephson parametric amplifier comprises a substrate, a coplanar waveguide disposed on the substrate, and a nonlinear resonator disposed on the substrate and coupled to the capacitor waveguide. The coplanar waveguide has an impedance that varies over a length of the coplanar waveguide Moreover, the coplanar waveguide comprises a conductor separated from a first ground plane by a first gap and a second ground plane by a second gap.

In one aspect, the nonlinear resonator comprises a capacitor disposed on the substrate and coupled to the coplanar waveguide, and one or more superconducting quantum interface devices disposed on the substrate and coupled to the capacitor. In another aspect, each superconducting quantum interface device comprises two Josephson junctions in parallel. In another aspect, the one or more superconducting quantum interface devices comprise two or more one or more superconducting quantum interface devices connected in series. In another aspect, the amplifier further comprises an input/output port disposed on the substrate and coupled to the coplanar waveguide, and one or more control ports disposed on the substrate and inductively coupled to the nonlinear resonator. In another aspect, the conductor, the first ground plane and the second ground plane comprise aluminum. In another aspect, the impedance of the waveguide is varied by: (1) increasing a width of the conductor over the length of the coplanar waveguide, or (2) coupling a plurality of dielectric bridges to the coplanar waveguide over the length of the coplanar waveguide. In another aspect, the impedance of the coplanar waveguide varies from about 50 ohms to about 15 ohms. In another aspect, each dielectric bridge comprises: a dielectric disposed within the first gap and the second gap, on a top of the first gap and the second gap, the conductor, and extending over a first portion of the first ground plane and a first portion of the second ground plane; and a metal disposed on a top of the dielectric and extending over a second portion of the first ground plane and a second portion of the second ground plane. In another aspect, the metal comprises aluminum, and the dielectric comprises aluminum oxide. In another aspect, the amplifier has one or more performance characteristics comprising: a gain of about 15-25 dB; a bandwidth of about 500 MHz bandwith; a tunable amplification band center; or a noise temperature near a quantum limit within the bandwidth.

In another embodiment of the present disclosure, a method of fabricating a wide-band Josephson parametric amplifier comprises: forming a first ground plane, a second ground plane, a conductor separated from the first ground plane by a first gap and the second ground plane by a second gap, a capacitor electrode, and a first resonator junction lead separated from a second resonator junction lead by a third gap on a substrate, wherein the conductor separated from the first ground plane by the first gap and the second ground plane by the second gap forms a coplanar waveguide; forming a capacitor on the capacitor electrode; forming one or more superconducting quantum interface devices by: (1) depositing a metal at a first angle on the substrate wherein a portion of the metal is deposited within the fourth gap next to the first resonator junction lead, (2) oxidizing an exposed portion of the metal deposited within a fourth gap next to the first resonator junction lead, and (3) depositing the metal at a second angle on the substrate within the forth gap next to the second resonator junction lead and overlapping a portion of the oxidized metal next to the first resonator junction lead; wherein the coplanar waveguide has an impedance that varies over a length of the coplanar waveguide; and wherein the capacitor is coupled between the coplanar waveguide and the one or more superconducting quantum interface devices.

In one aspect, the method is performed using a lift-off process, a selective etch process, or a combination thereof. In another aspect, the first angle comprises about 30 to 45 degrees, and the second angle comprises about −30 to −45 degrees. In another aspect, the first angle comprises about 31.5 degrees, and the second angle comprises about −31.5 degrees. In another aspect, the one or more superconducting quantum interface devices are formed before the capacitor is formed. In another aspect, each superconducting quantum interface device comprises two Josephson junctions in parallel. In another aspect, the one or more superconducting quantum interface devices comprise two or more one or more superconducting quantum interface devices connected in series. In another aspect, the method further comprises forming an input/output port disposed on the substrate and coupled to the coplanar waveguide, and forming one or more control ports disposed on the substrate that are inductively coupled to the one or more superconducting quantum interface devices. In another aspect, the conductor, the first ground plane and the second ground plane comprise aluminum. In another aspect, the impedance of the waveguide is varied by: (1) increasing a width of the conductor over the length of the coplanar waveguide, or (2) coupling a plurality of dielectric bridges to the coplanar waveguide over the length of the coplanar waveguide. In another aspect, the impedance of the coplanar waveguide varies from about 50 ohms to about 15 ohms. In another aspect, the method further comprises forming the plurality of dielectric bridges by: depositing a first photoresist coating; exposing the first photoresist coating in accordance with a first pattern; depositing a metal oxide according to the first pattern: (1) within the first gap and the second gap, (2) on a top of the first gap, the conductor and the second gap, and (3) extending over a first portion of the first ground plane and a first portion of the second ground plane; removing the first photoresist coating; depositing a second photoresist coating; exposing the second photoresist coating in accordance with a second pattern; depositing the metal on a top of the metal oxide and extending over a second portion of the first ground plane and a second portion of the second ground plane; and removing the second photoresist coating. In another aspect, the metal oxide comprises aluminum oxide. In another aspect, forming the capacitor comprises depositing a metal oxide on a top of the capacitor electrode, and depositing the metal on a top of the metal oxide. In another aspect, the capacitor electrode comprises a first capacitor electrode separated from a second capacitor electrode by a fourth gap and forming the capacitor comprises: (1) depositing a metal oxide on a top of the first capacitor electrode, a side of the first capacitor electrode within the third gap, a top of the second capacitor electrode, and a side of the second capacitor electrode within the third gap, (2) depositing the metal within a remaining portion of the third gap and a top of the metal oxide over the first capacitor electrode and the second capacitor electrode, and (3) depositing the metal on a portion of the first capacitor electrode, a side of the metal oxide and a side of the metal on top of the metal oxide. In another aspect, the amplifier has one or more performance characteristics comprising: a gain of about 15-25 dB; a bandwidth of about 500 MHz bandwith; a tunable amplification band center; or a noise temperature near a quantum limit within the bandwidth.

In another embodiment of the present disclosure, a wide-band Josephson parametric amplifier fabricated in accordance with the above-described method.

### BRIEF DESCRIPTION OF THE DRAWINGS

For a more complete understanding of the features and advantages of the present invention, reference is now made to the detailed description of the invention along with the accompanying figures, in which:

FIGS. 1A-1C are diagrams of a wide-band Josephson parametric amplifier in accordance with one embodiment of the present disclosure;

FIGS. 2A-2H depict a method of fabricating a wide-band Josephson parametric amplifier in accordance with one embodiment of the present disclosure;

FIGS. 3A-3D are diagrams of a wide-band Josephson parametric amplifier in accordance with another embodiment of the present disclosure;

FIGS. 4A-4H depict a method of fabricating a wide-band Josephson parametric amplifier in accordance with another embodiment of the present disclosure;

FIG. 5 is an image of a wide-band Josephson parametric amplifier in accordance with another embodiment of the present disclosure;

FIG. 6 is an image of a wide-band Josephson parametric amplifier in accordance with another embodiment of the present disclosure;

FIG. 7 is a wiring diagram for measuring the signal gain of a wide-band Josephson parametric amplifier in accordance with another embodiment of the present disclosure;

FIGS. 8A and 8B are graphs showing performance data of a wide-band Josephson parametric amplifier in accordance with another embodiment of the present disclosure;

FIG. 9 depicts a method of fabricating a wide-band Josephson parametric amplifier in accordance with another embodiment of the present disclosure;

FIG. 10 is a graph of the system noise temperature of the wide-band Josephson parametric amplifier compared to the quantum noise limit in accordance with another embodiment of the present disclosure;

FIG. 11 is a graph of the signal gain versus frequency of the wide-band Josephson parametric amplifier compared to the quantum noise limit in accordance with another embodiment of the present disclosure; and

FIG. 12 is a graph of the real gain versus frequency of the wide-band Josephson parametric amplifier compared to the quantum noise limit in accordance with another embodiment of the present disclosure.

### DETAILED DESCRIPTION OF THE INVENTION

Illustrative embodiments of the system of the present application are described below. In the interest of clarity, not all features of an actual implementation are described in this specification. It will of course be appreciated that in the development of any such actual embodiment, numerous implementation-specific decisions must be made to achieve the developer's specific goals, such as compliance with system-related and business-related constraints, which will vary from one implementation to another. Moreover, it will be appreciated that such a development effort might be complex and time-consuming but would nevertheless be a routine undertaking for those of ordinary skill in the art having the benefit of this disclosure.

Various embodiments of the present disclosure provide a simple fabrication process because the resonators and Josephson junctions are combined into a single ebeam lithographic process. In some embodiments, only one additional lithographic process was added for making aluminum dielectric bridges to achieve the broadband amplification performance. The aluminum dielectric bridges lower the effective external impedance for lowering the quality factor, which achieves broad bandwidth. Moreover, the simplicity of the fabrication process makes it feasible to mass manufacture this wide-band Josephson parametric amplifier chip. Moreover, its broadband and low-noise amplification feature makes this chip a very promising component in commercializing multi-qubit quantum processors. The wide-band Josephson parametric amplifier in accordance with various embodiments of the present disclosure provides: (1) state-of-the-art gain among quantum-limit applifiers, namely 15-25 dB; (2) wideband quantum-limit amplification of about 500 MHz bandwith; (3) a high-yield, simple and robust nano-fabrication process; (4) a tunable amplification band center; and/or (5) a noise temperature near a quantum limit within the bandwidth.

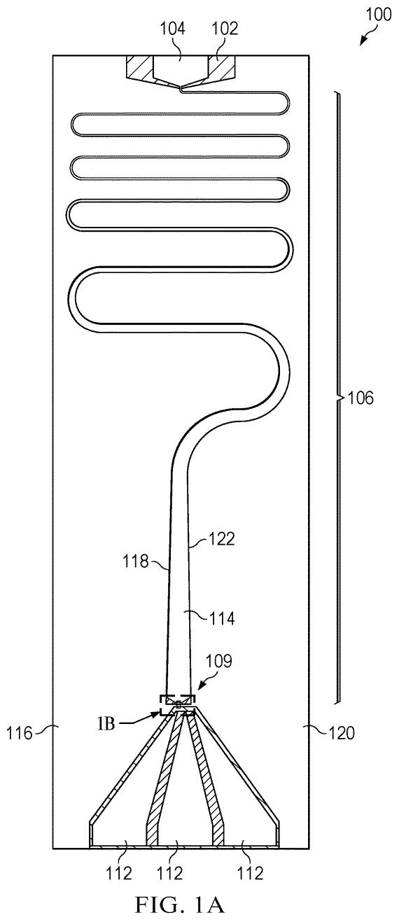

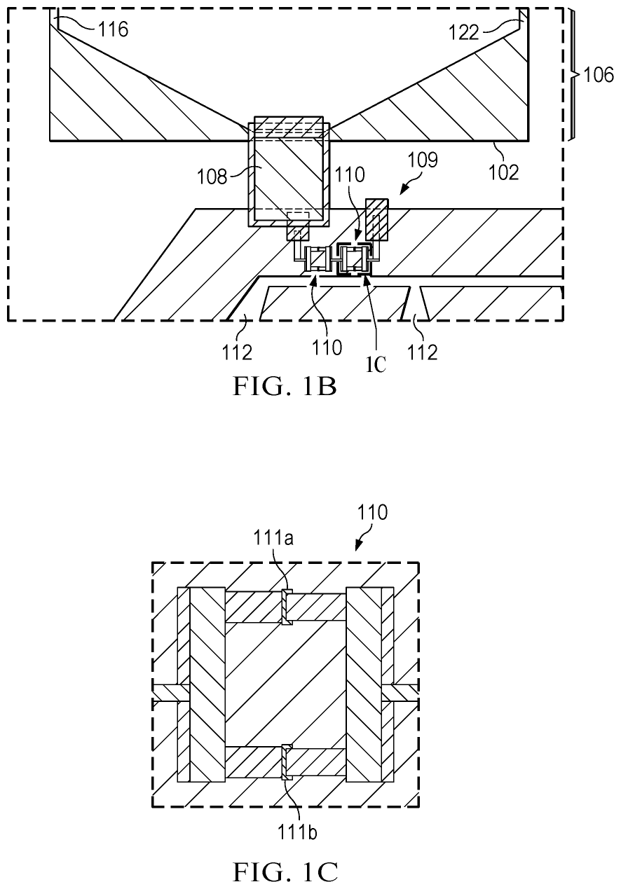

Now referring to FIGS. 1A-1C, diagrams of a wide-band Josephson parametric amplifier 100 in accordance with one embodiment of the present disclosure are shown. The wide-band Josephson parametric includes 100 comprises a substrate 102, an input/output port 104 disposed on the substrate 102, a coplanar waveguide 106 disposed on the substrate 102 and coupled to the input/output port 104, a nonlinear resonator 109 disposed on the substrate 102 and coupled to the coplanar waveguide 106, and one or more control ports 112 disposed on the substrate 102 and inductively coupled to the nonlinear resonator 109. The coplanar waveguide 106 has an impedance that varies over a length of the coplanar waveguide 106. In the embodiment shown, the coplanar waveguide 106 comprises a conductor 114 separated from a first ground plane 116 by a first gap 118 and a second ground plane 120 by a second gap 122. In this example, the impedance of the coplanar waveguide 106 is varied by increasing a width of the conductor over the length of the coplanar waveguide 106. In a non-limiting example, the impedance of the coplanar waveguide 106 varies from about 50 ohms to about 15 ohms. Note that the dimensions, shape and length of coplanar waveguide 106 can be any suitable dimensions, shape and length as determined by those skilled in the art. The conductor 114, the first ground plane 116 and the second ground plane 120 can be aluminum, or any other conductor suitable for use with the amplifier as determined by those skilled in the art. The one or more control ports 112 are used to tune the center frequency of the amplification band and also tune the amplifier to its operational point.

As shown in FIG. 1B, the nonlinear resonator 109 can be a capacitor 108 disposed on the substrate 102 and coupled to the coplanar waveguide 106, and one or more superconducting quantum interface devices (SQUID) 110 disposed on the substrate 102 and coupled to the capacitor 108. Moreover, the one or more superconducting quantum interface devices 110 can be two or more one or more superconducting quantum interface devices 110 connected in series (i.e., a SQUID array) to get a larger nonlinear inductance. Each superconducting quantum interface device 110 can be two Josephson junctions 111a, 111b in parallel as shown in FIG. 1C. The superconducting quantum interface device 110 is a tunable nonlinear inductor whose inductance can be tuned by a magnetic flux through the area between the two parallel Josephson junctions 111a, 111b. The one or more superconcuding quantum interface devices 110 are inductively coupled to the one or more control ports 112. In addition, the dimensions and shape of the nonlinear resonator 109 can be any suitable dimension or shape as determined by those skilled in the art.

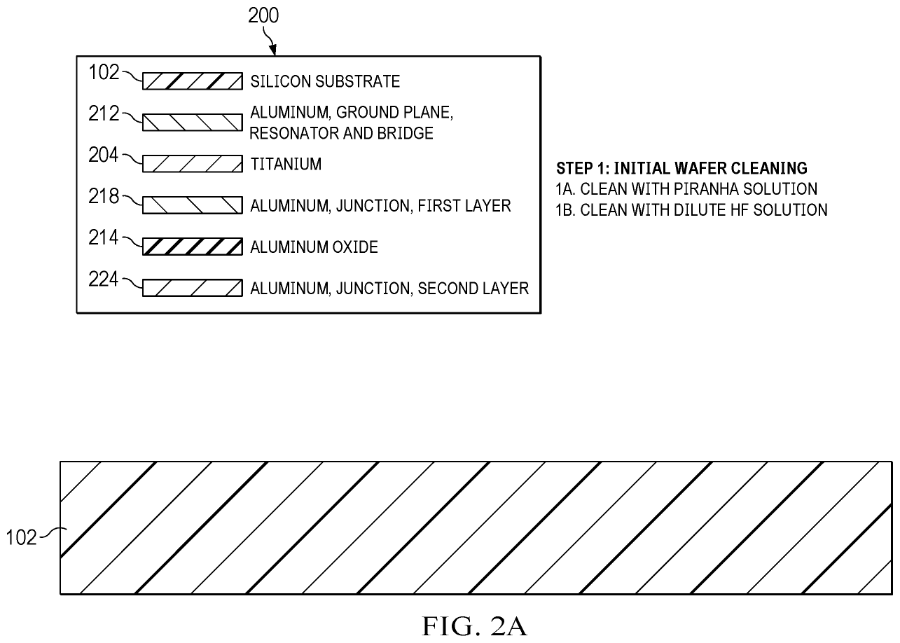

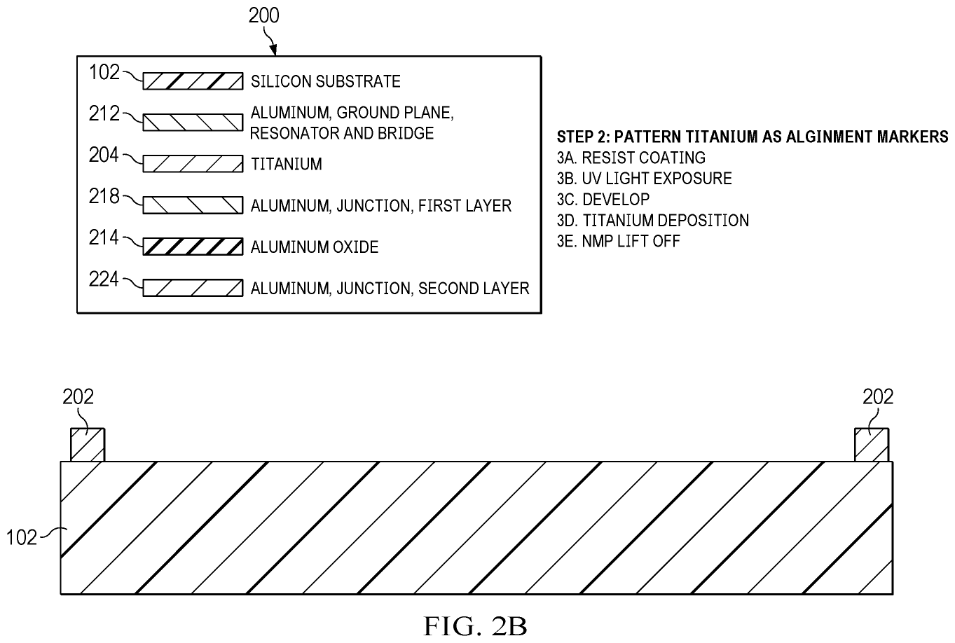

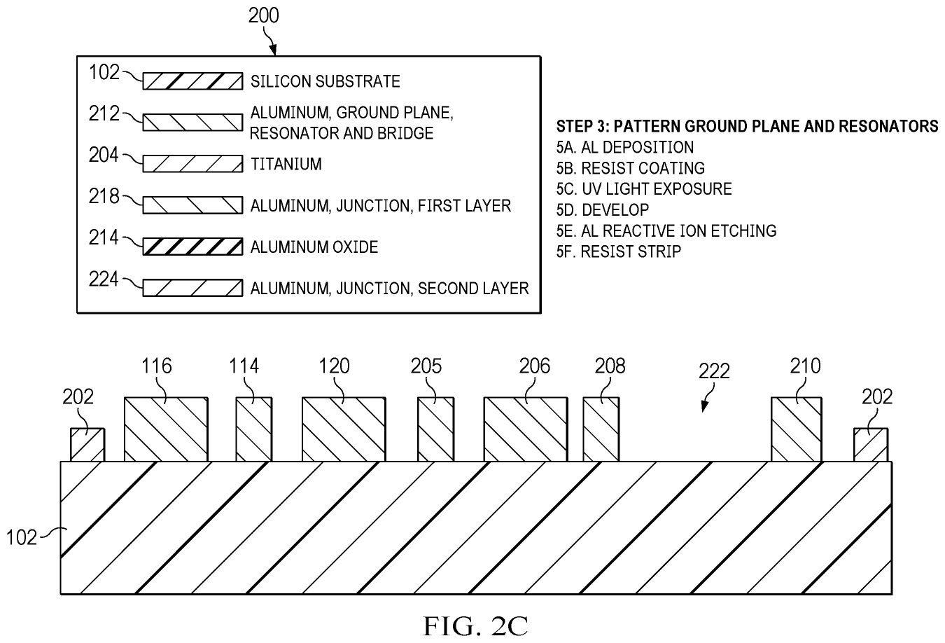

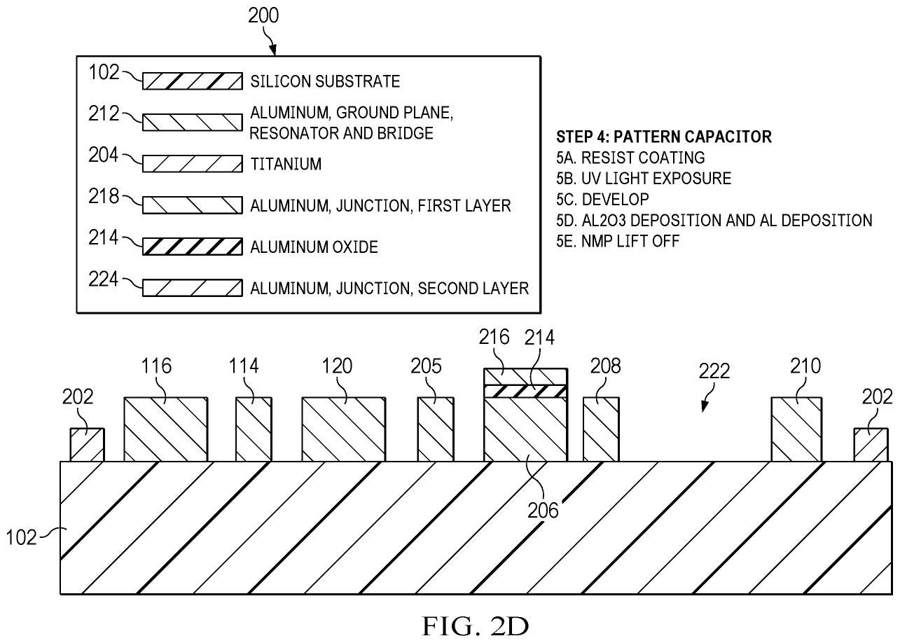

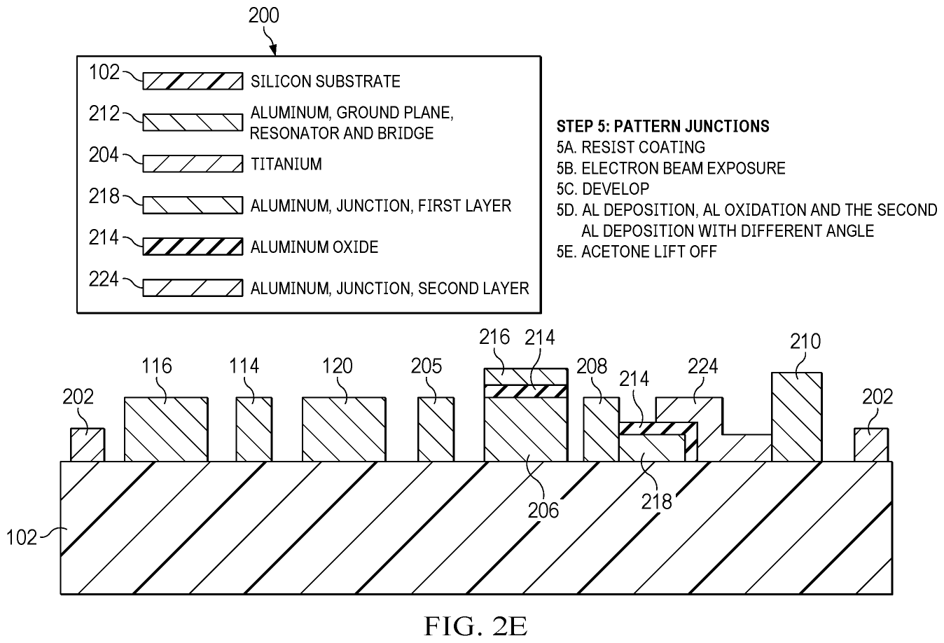

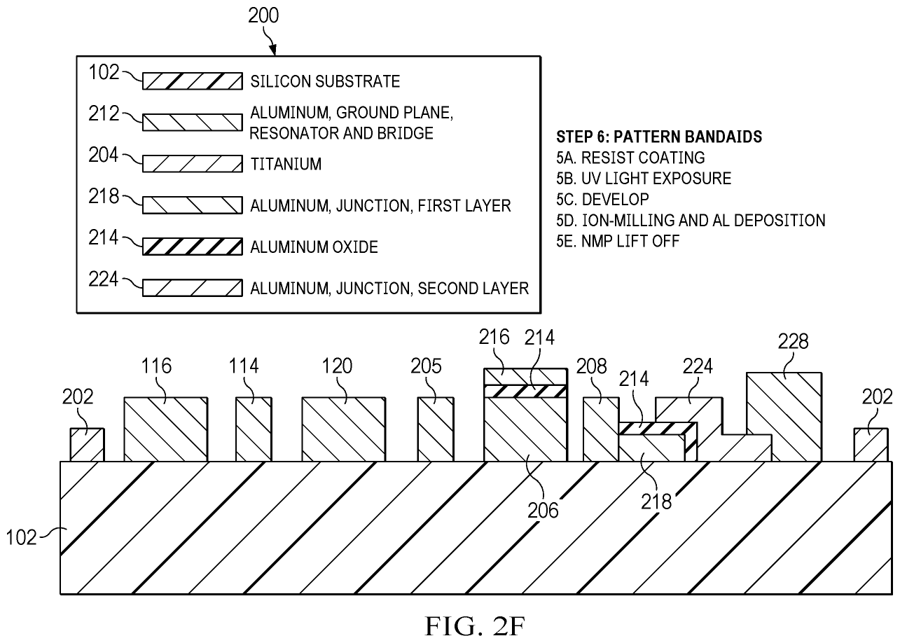

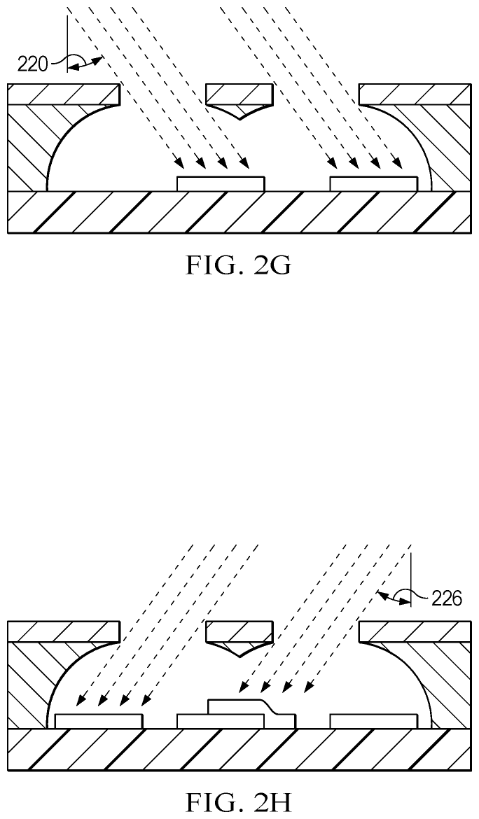

Referring now to FIGS. 2A-2H, a method 200 of fabricating a wide-band Josephson parametric amplifier in accordance with one embodiment of the present disclosure is shown. The method 200 can use a lift-off process, a selective etch process, or a combination thereof. In Step 1 (FIG. 2A), the wafer, such as a silicon substrate 102, is cleaned by using a Piranha solution and a dilute hydrofluoric acid (HF) solution. In Step 2 (FIG. 2B), alignment markers 202 are formed by: applying a resist coating, exposing the resist coating to a UV light in accordance with a first pattern for the alignment markers 202, developing the first pattern, depositing titanium 204, and lifting off the resist coating using a solvent, such as N-methyl-2-pyrrolidone (NMP). In Step 3 (FIG. 2C), a first ground plane 116, conductor 114 and second ground plane 120 (all for the coplanar waveguide), a capacitor electrode 206, a first resonator junction lead 208 and second resonator junction lead 210 are formed out of aluminum 212 by: depositing a layer of aluminum 212 on the substrate 102, applying a resist coating on the aluminum 212, exposing the resist coating to a UV light in accordance with a second pattern for the ground planes, conductor, capacitor and resonator, developing the second pattern, etching the aluminum layer 212 using a reactive ion etching process, and stripping off the resist coating. In some embodiments, an additional capacitor electrode 205 may be used depending on the architecture used for the capacitor. Note that the coplanar waveguide has an impedance that varies over a length of the coplanar waveguide by increasing a width of the conductor over the length of the coplanar waveguide. In Step 4 (FIG. 2D), the capacitor is formed by: applying a resist coating, exposing the resist coating to a UV light in accordance with a third pattern for the capacitor, developing the third pattern, depositing an aluminum oxide layer 214 on the capacitor electrode 206, depositing an aluminum layer 216 on the aluminum oxide layer 214, and lifting off the resist coating. In Step 5 (FIG. 2E), one or more superconducting quantum interface devices and superconducting Josephson junctions are formed by: applying a resist coating, exposing the resist coating to an electron beam in accordance with a fourth pattern, developing the fourth pattern, depositing aluminum 218 at a first angle 220 (FIG. 2G) according to the fourth pattern wherein a portion of the aluminum 218 is deposited within a gap 222 (see Step 3, FIG. 2C) next to the first resonator junction lead 208, oxidizing the exposed portion of the aluminum 218 deposited within the gap 222 (see Step 3, FIG. 2C) next to the first resonator junction lead 208, depositing the aluminum 224 at a second angle 226 (FIG. 2H) within the gap 222 (see Step 3, FIG. 2C) next to the second resonator junction lead 210 and overlapping a portion of the aluminum oxide 214 next to the first resonator junction lead 208, and lifting off the resist coating using a solvent, such as NMP. The the first angle 220 can be about 30 to 45 degrees and the second angle 226 can be about −30 to −45 degrees, or any desired increment in between. In some embodiments, the first angle 220 can be about 31.5 degrees and the second angle 226 can be about −31.5 degrees. In Step 6 (FIG. 2F), bandaids 228 are formed by: applying a resist coating, exposing the resist coating to a UV light in accordance with a fifth pattern, developing the fifth pattern, ion milling and aluminum deposition of the bandaids 228 on top of the second resonator junction lead 210 and inside of the second resonator junction lead 210 on a portion of the aluminum 224, and lifting off the resist coating using a solvent, such as NMP.

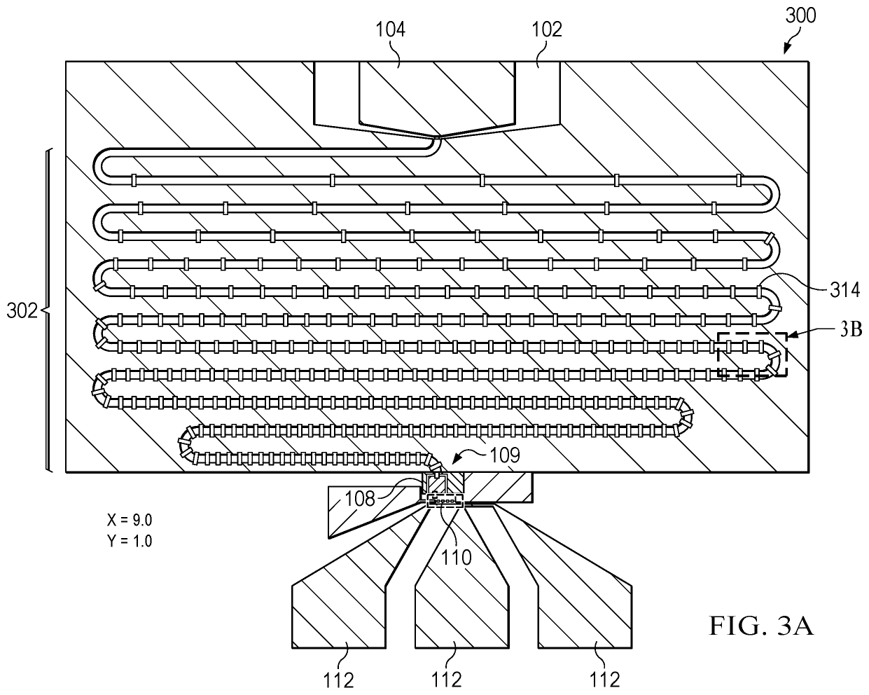

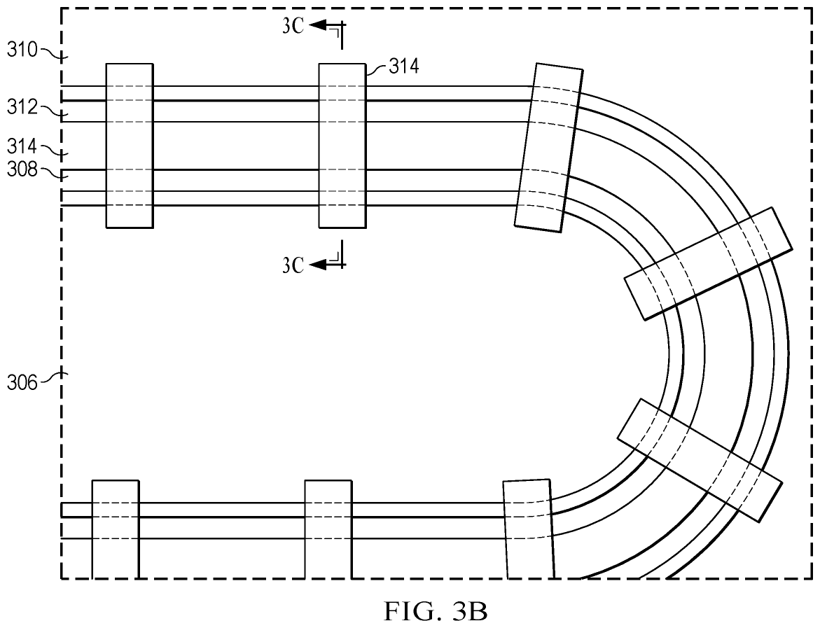

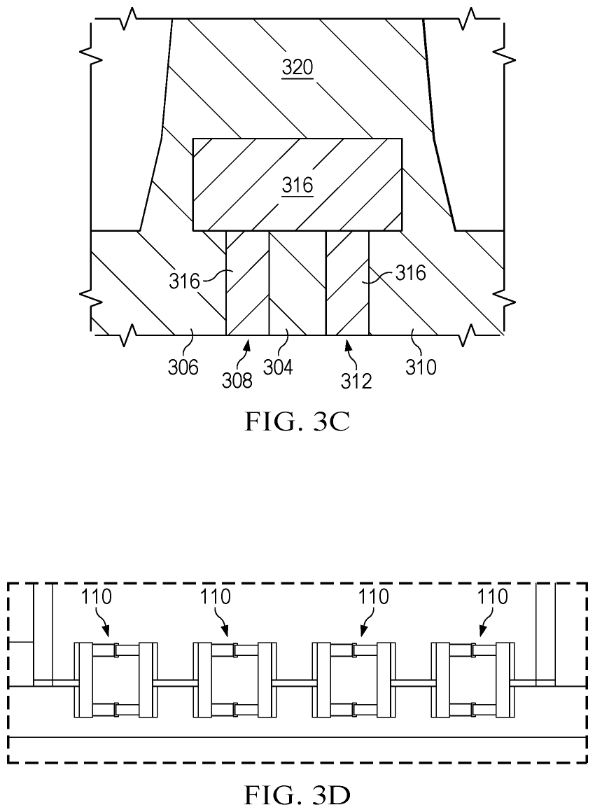

Now referring to FIGS. 3A-3D, diagrams of a wide-band Josephson parametric amplifier 300 in accordance with one embodiment of the present disclosure are shown. The wide-band Josephson parametric includes 300 comprises a substrate 102, an input/output port 104 disposed on the substrate 102, a coplanar waveguide 302 disposed on the substrate 102 and coupled to the input/output port 104, a nonlinear resonator 109 disposed on the substrate 102 and coupled to the coplanar waveguide 302, and one or more control ports disposed 112 on the substrate 102 and inductively coupled to the nonlinear resonator 109. The nonlinear resonator 109 includes a capacitor 108 disposed on the substrate 102 and coupled to the coplanar waveguide 302, and one or more superconducting quantum interface devices 110 disposed on the substrate 102 and coupled to the capacitor 108.

The coplanar waveguide 106 has an impedance that varies over a length of the coplanar waveguide 106. In the embodiment shown in FIG. 3B, the coplanar waveguide 302 comprising a conductor 304 separated from a first ground plane 306 by a first gap 308 and a second ground plane 310 by a second gap 312. In this example, the impedance of the coplanar waveguide 302 is varied by coupling a plurality of dielectric bridges 314 to the coplanar waveguide 302 over the length of the coplanar waveguide 302. As shown in the cross-section of FIG. 3C, each dielectric bridge 314 comprises: (1) a dielectric 316 disposed within the first gap 308 and the second gap 312, on a top of the first gap 308 and the second gap 312, the conductor 304, and extending over a first portion of the first ground plane 306 and a first portion of the second ground plane 310; and (3) a metal 320 disposed on a top of the dielectric 316 and extending over a second portion of the first ground plane 306 and a second portion of the second ground plane 310. In a non-limiting example, the impedance of the coplanar waveguide 106 varies from about 50 ohms to about 15 ohms. This is accomplished by reducing the distance between the dielectric bridges 314 between the input/output port 104 to the capacitor 108. Note that the dimensions, shape and length of coplanar waveguide 302 and dielectric bridges 312 can be any suitable dimensions, shape and length as determined by those skilled in the art. Note that other types of bridges can be used, such as an air bridge.

Moreover, each superconducting quantum interface device 110 can be two Josephson junctions 111a, 111b in parallel as shown in FIG. 1C. In addition, the one or more superconducting quantum interface devices 110 can be two or more one or more superconducting quantum interface devices 110 connected in series, such as four as shown in FIG. 3D. In addition, the dimensions and shape of the one or more superconducting quantum interface devices 110 can be any suitable dimension or shape as determined by those skilled in the art. The conductor 304, the first ground plane 306, the second ground plane 310 and the metal 320 can be aluminum, or any other conductor suitable for use with the amplifier as determined by those skilled in the art. The dielectric 316 can be aluminum oxide, or any other dielectric suitable for use with the amplifier as determined by those skilled in the art. In another aspect, the amplifier has one or more performance characteristics comprising: a gain of about 15-25 dB; a bandwidth of about 500 MHz bandwith; or a tunable amplification band center.

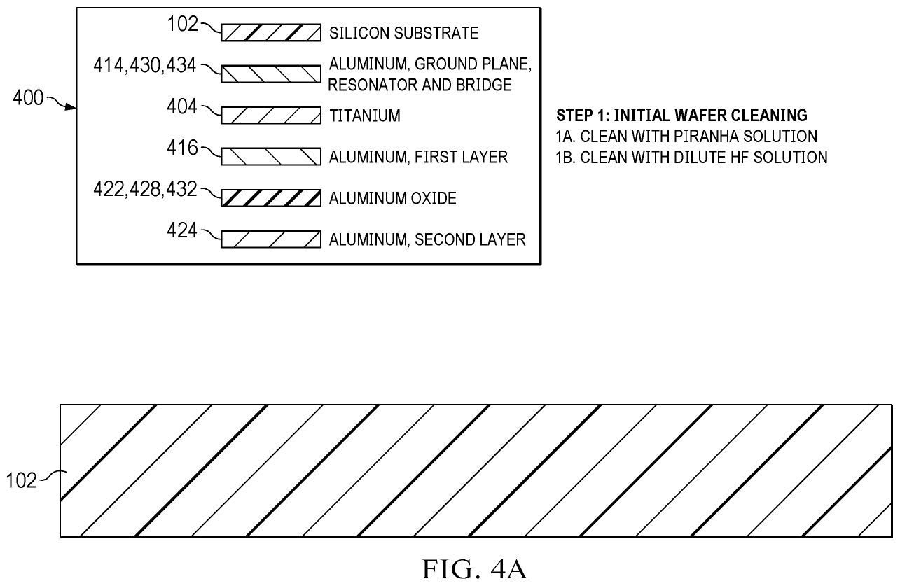

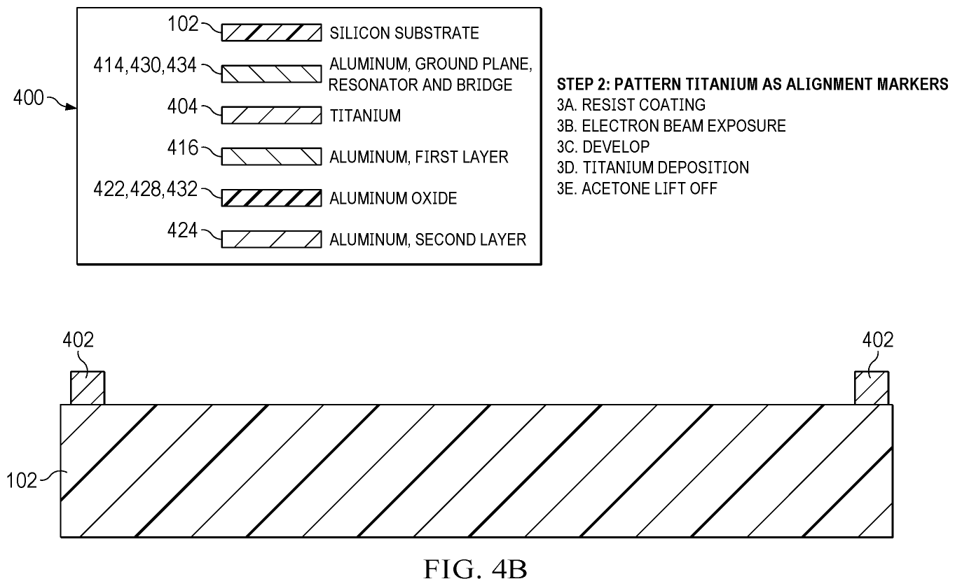

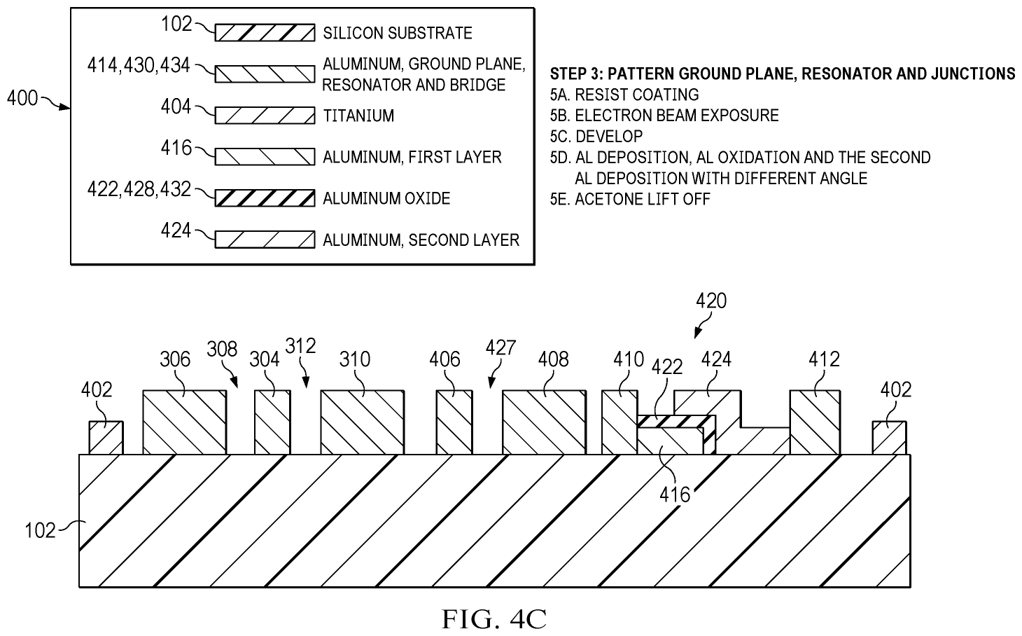

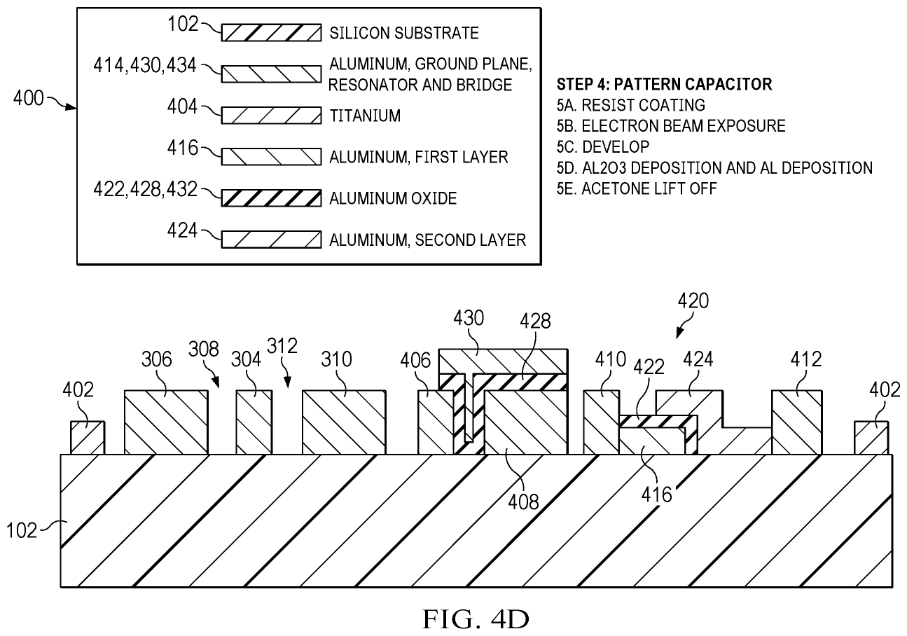

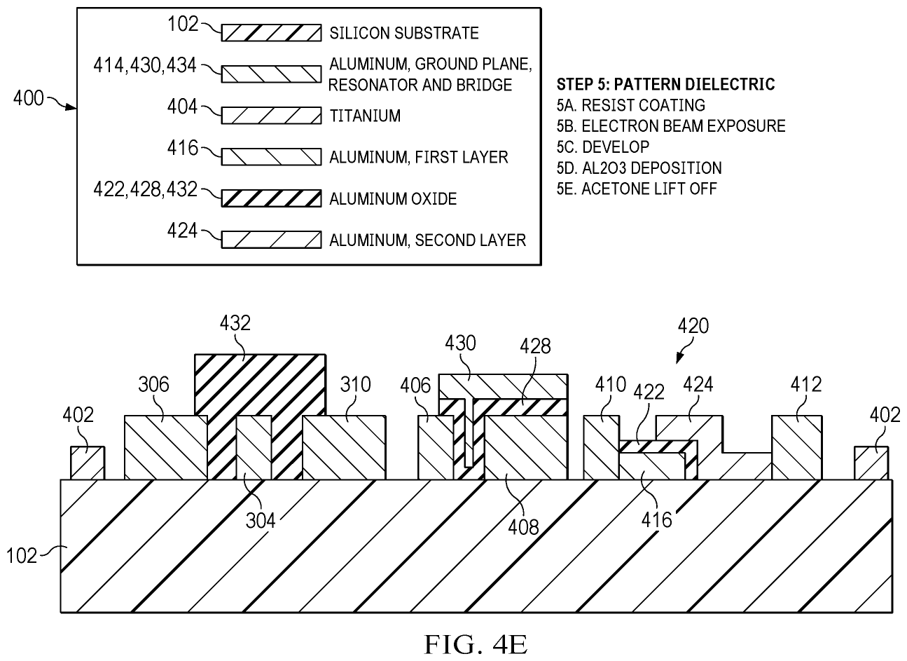

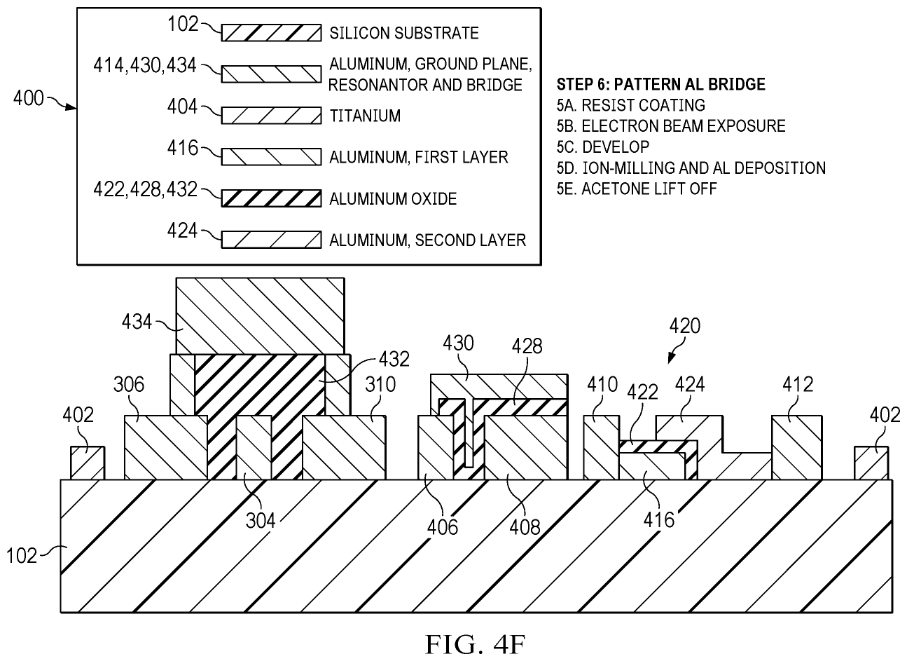

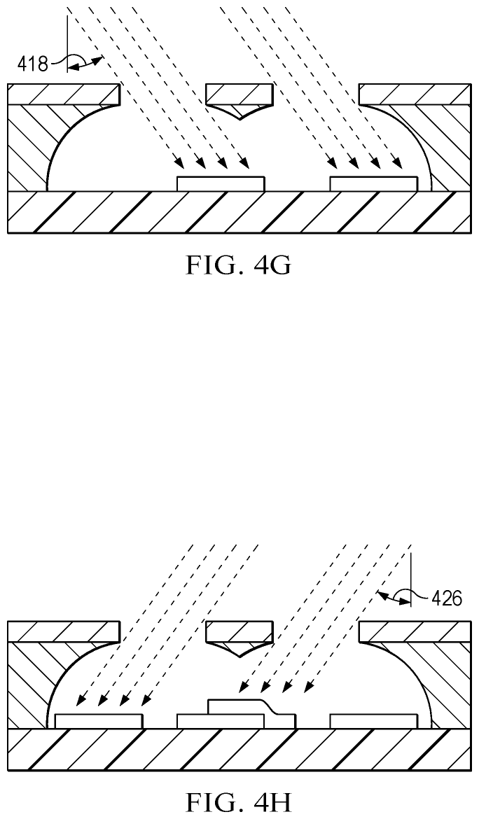

Referring now to FIGS. 4A-4H, a method 400 of fabricating a wide-band Josephson parametric amplifier in accordance with one embodiment of the present disclosure is shown. The method 400 can use a lift-off process, a selective etch process, or a combination thereof. In Step 1 (FIG. 4A), the wafter, such as a silicon substrate 102, is cleaned by using a Piranha solution and a dilute hydrofluoric acid (HF) solution. In Step 2 (FIG. 4B), alignment markers 402 are formed by: applying a resist coating, exposing the resist coating to a UV light in accordance with a first pattern for the alignment markers 402, developing the first pattern, depositing titanium 404, and lifting off the resist coating using a solvent, such as acetone. In Step 3 (FIG. 4C), a first ground plane 306, conductor 304 and second ground plane 310 (all for the coplanar waveguide), a first capacitor electrode 406, a second capacitor electrode 408, a first resonator junction lead 410 and second resonator junction lead 412 are formed out of aluminum 414 by: applying a resist coating on the substrate 102, exposing the resist coating to an electron beam in accordance with a second pattern for the ground planes, conductor, capacitor electrodes and resonator junction leads, developing the second pattern, depositing aluminum 414 for a first ground plane 306, conductor 304 and second ground plane 310 (all for the coplanar waveguide), a first capacitor electrode 406, a second capacitor electrode 408, a first resonator junction lead 410 and second resonator junction lead 412, depositing aluminum 416 at a first angle 418 (FIG. 4G) according to the second pattern wherein a portion of the aluminum 416 is deposited within a gap 420 next to the first resonator junction lead 410, oxidizing the exposed portion of the aluminum 416 deposited within the gap 420 next to the first resonator junction lead 410, depositing the aluminum 424 at a second angle 426 (FIG. 4H) within the gap 420 next to the second resonator junction lead 412 and overlapping a portion of the aluminum oxide 424 next to the first resonator junction lead 410, and lifting off the resist coating using a solvent, such as acetone. The the first angle 418 can be about 30 to 45degrees and the second angle 426 can be about −30 to −45 degrees, or any desired increment in between. In some embodiments, the first angle 418 can be about 31.5 degrees and the second angle 426 can be about −31.5 degrees. In Step 4 (FIG. 4D), the capacitor is formed by: applying a resist coating, exposing the resist coating to a UV light in accordance with a third pattern for the capacitor, developing the third pattern, depositing a metal oxide 428 on a top of the first capacitor electrode 406, a side of the first capacitor electrode 406 within the third gap 427 (see Step 3, FIG. 4C), a top of the second capacitor electrode 408, and a side of the second capacitor electrode 408 within the third gap 427 (see Step 3, FIG. 4C), and (2) depositing aluminum 430 within a remaining portion of the third gap 427 (see Step 3, FIG. 4C) and a top of the metal oxide 428 over the first capacitor electrode 406 and the second capacitor electrode 408. Alternatively, the third gap 427 can be filled completely with aluminum 430. In Step 5 (FIG. 4E), a dielectric is patterned for a plurality of dielectric bridges 314 by: depositing a resist coating; exposing the resist coating to an electron beam in accordance with a fourth pattern; developing the fourth pattern, depositing aluminum oxide 432 according to the fourth pattern: (1) within the first gap 308 (see Step 3, FIG. 4C) and the second gap 312 (see Step 3, FIG. 4C), (2) on a top of the first gap 308 (see Step 3, FIG. 4C), the conductor 304 and the second gap 312 (see Step 3, FIG. 4C), and (3) extending over a first portion of the first ground plane 306 and a first portion of the second ground plane 310; and lifting off the resist coating using a solvent, such as acetone. In Step 6 (FIG. 4F), aluminum is patterned for the plurality of dielectric bridges 314 by: depositing a resist coating; exposing the resist coating to an electron beam in accordance with a fifth pattern; developing the fifth pattern, depositing aluminum 434 on a top of the metal oxide 432 and extending over a second portion of the first ground plane 306 and a second portion of the second ground plane 310; and lifting off the resist coating using a solvent, such as acetone.

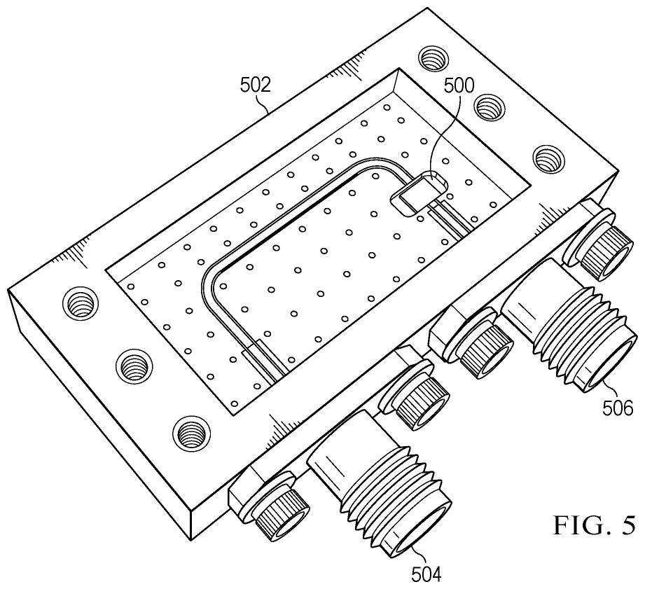

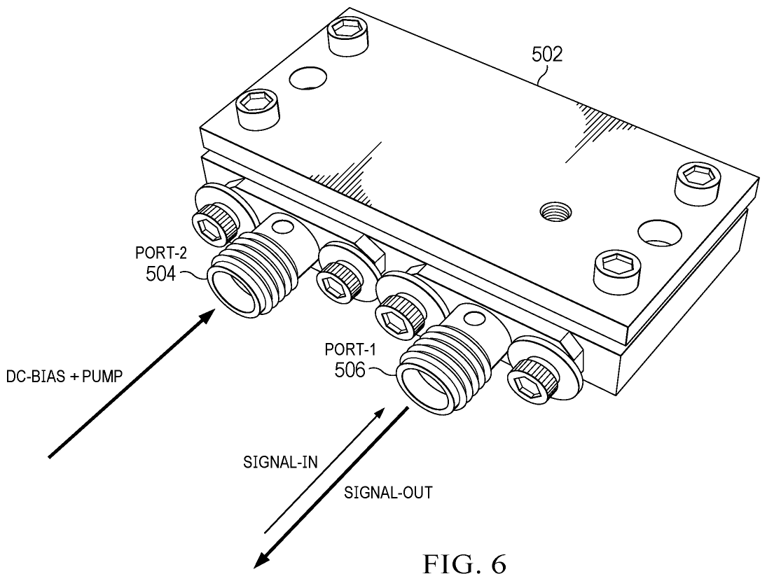

Now referring to FIGS. 5-6, images of a wide-band Josephson parametric amplifier 500 in accordance with another embodiment of the present disclosure are shown. The wide-band Josephson parametric amplifier 500 is mounted within housing 502 and connected to Port 2 504 (DC Bias+Pump) and Port 1 506 (Signal-IN and Signal-OUT). In this embodiment, SMA port (Port 2 504) is for RF parametric pump to drive the parametric amplification of the signal and also DC flux biasing of the nonlinear resonator to cause the amplification at its operational point, while the other SMA port (Port 1 506) is for a weak signal-in and amplified signal-out.

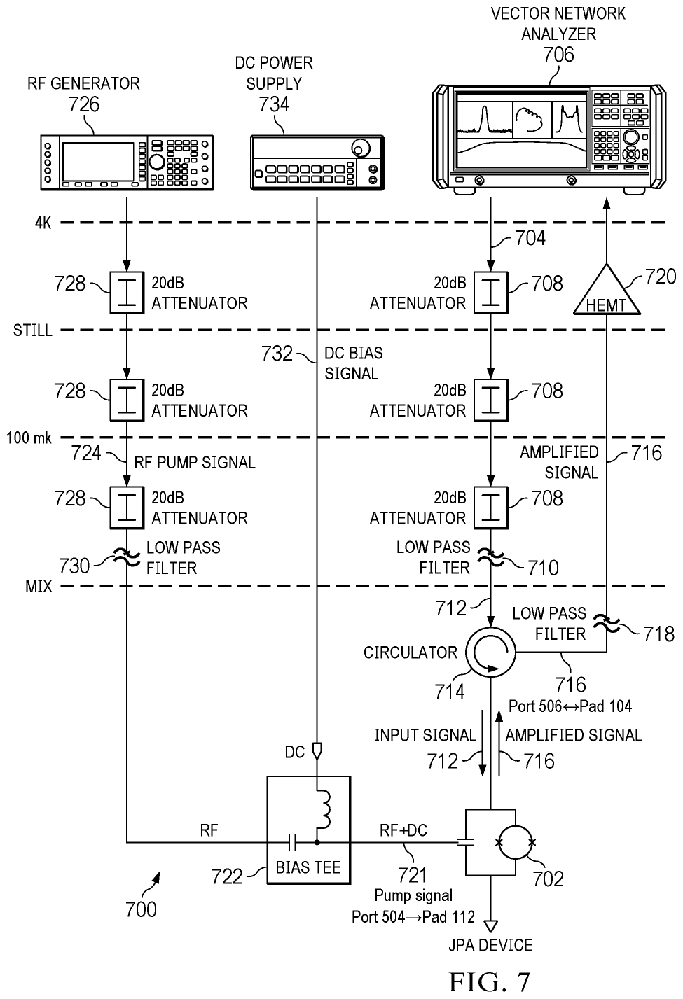

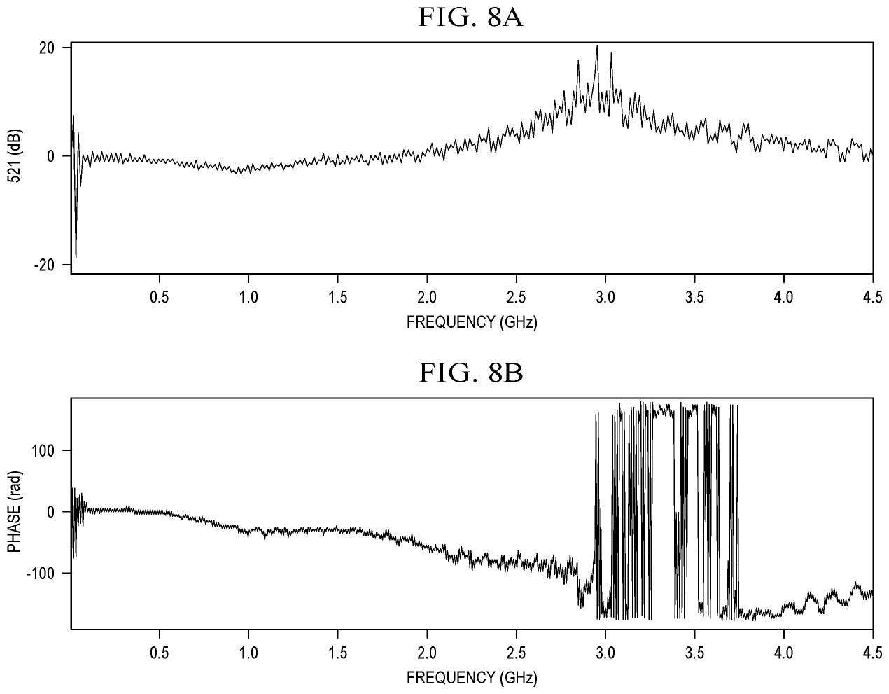

Referring now to FIG. 7, a wiring diagram 700 for measuring the signal gain of a wide-band Josephson parametric amplifier 702 in accordance with another embodiment of the present disclosure are shown. An input signal 704 is generated by a vector network analyzer 706 and is weakened using a set of 20 dB attenuators 708 and low pass filter 710. The resulting weak input signal 712 goes through a circulator 714 which routes the signal 712 into Port 1 506 of the wide-band Josephson parametric amplifier 702. The weak input signal 712 then goes into the coplanar waveguide (using varying width coplanar waveguide or dielectric bridges with varying spacings), and subsequently interacts with the nonlinear resonator pumped via the DC Bias+Pump signal 714 into Port 2 504 of the wide-band Josephson parametric amplifier 702. The weak input signal 712 is then parametrically amplified and reflected from the nonlinear resonator back to the on-chip impedance transformer line and back out of Port 1 506. The output signal 716 is amplified and the circulator 714 routes the output reflected amplified signal 716 to the vector network analyzer 706 via a low pass filter 718 and HEMT amplifier 720. Note that the input and output signals 712 and 716 can be isolated such that the circulator 714 is eliminated. The DC Bias+Pump signal 721 is generated using a bias tree 722 that combines: (1) the RF pump signal 724 from a RF generator 726 and a set of 20 dB attenuators 728 and low pass filter 730 with (2) the DC bias signal 732 from a DC power supply 734. Graphs showing performance data of a wide-band Josephson parametric amplifier 702 using the wiring diagram of FIG. 7 is shown in FIGS. 8A and 8B.

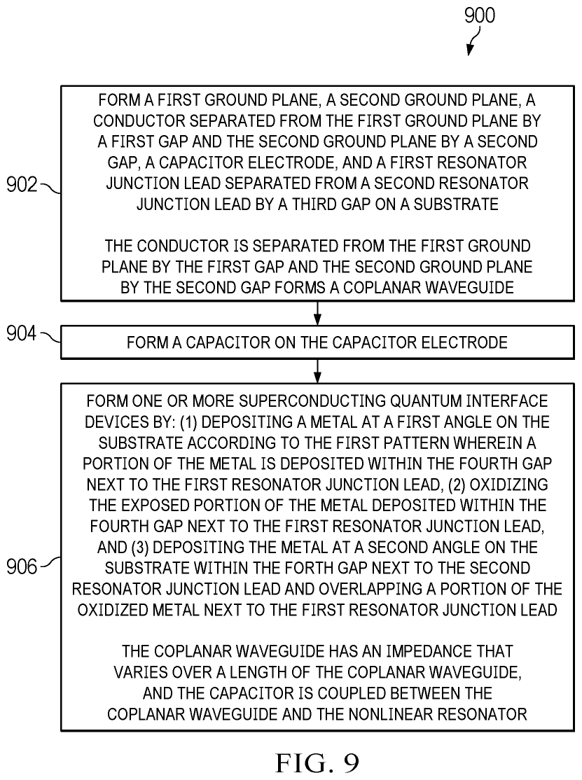

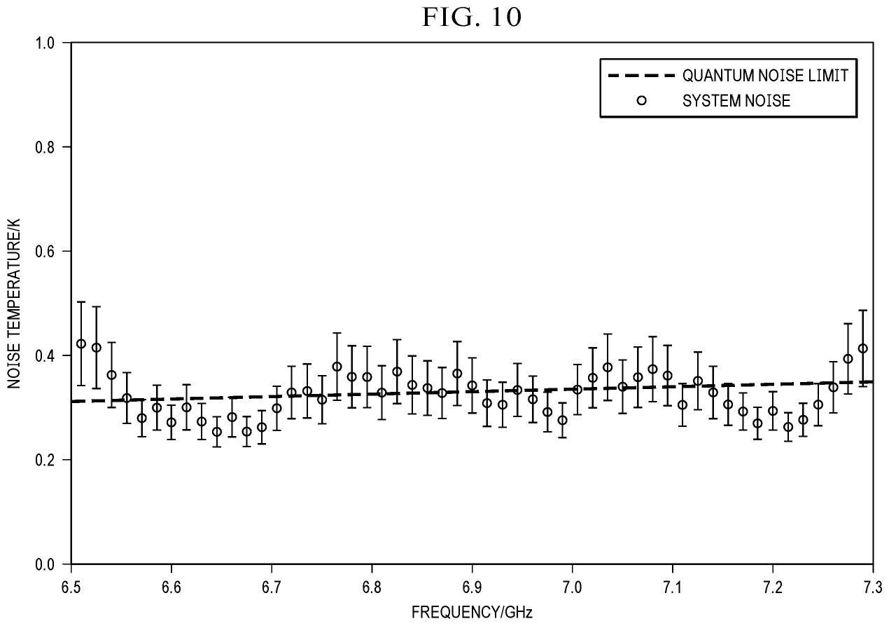

Referring now to FIG. 9, a method 900 of fabricating a wide-band Josephson parametric amplifier in accordance with one embodiment of the present disclosure is shown. A first ground plane, a second ground plane, a conductor separated from the first ground plane by a first gap and the second ground plane by a second gap, a capacitor electrode, and a first resonator junction lead separated from a second resonator junction lead by a third gap on a substrate are formed in block 902. The conductor is separated from the first ground plane by the first gap and the second ground plane by the second gap forms a coplanar waveguide. A capacitor is formed on the capacitor electrode in block 904. One or more superconducting quantum interface devices are formed in block 906 by: (1) depositing a metal at a first angle on the substrate wherein a portion of the metal is deposited within a fourth gap next to the first resonator junction lead, (2) oxidizing an exposed portion of the metal deposited within the fourth gap next to the first resonator junction lead, and (3) depositing the metal at a second angle on the substrate within the forth gap next to the second resonator junction lead and overlapping a portion of the oxidized metal next to the first resonator junction lead. The coplanar waveguide has an impedance that varies over a length of the coplanar waveguide, and the capacitor is coupled between the coplanar waveguide and the nonlinear resonator.

In one aspect, the method is performed using a lift-off process, a selective etch process, or a combination thereof. In another aspect, the first angle comprises about 30 to 45 degrees, and the second angle comprises about −30 to −45 degrees. In another aspect, the first angle comprises about 31.5 degrees, and the second angle comprises about −31.5 degrees. In another aspect, the one or more superconducting quantum interface devices are formed before the capacitor is formed. In another aspect, each superconducting quantum interface device comprises two Josephson junctions in parallel. In another aspect, the one or more superconducting quantum interface devices comprise two or more one or more superconducting quantum interface devices connected in series. In another aspect, the method further comprises forming an input/output port disposed on the substrate and coupled to the coplanar waveguide, and forming one or more control ports disposed on the substrate that are inductively coupled to the one or more superconducting quantum interface devices. In another aspect, the conductor, the first ground plane and the second ground plane comprise aluminum. In another aspect, the impedance of the waveguide is varied by: (1) increasing a width of the conductor over the length of the coplanar waveguide, or (2) coupling a plurality of dielectric bridges to the coplanar waveguide over the length of the coplanar waveguide. In another aspect, the impedance of the coplanar waveguide varies from about 50 ohms to about 15 ohms. In another aspect, the method further comprises forming the plurality of dielectric bridges by: depositing a first photoresist coating; exposing the first photoresist coating in accordance with a first pattern; depositing a metal oxide according to the first pattern: (1) within the first gap and the second gap, (2) on a top of the first gap, the conductor and the second gap, and (3) extending over a first portion of the first ground plane and a first portion of the second ground plane; removing the first photoresist coating; depositing a second photoresist coating; exposing the second photoresist coating in accordance with a second pattern; depositing the metal on a top of the metal oxide and extending over a second portion of the first ground plane and a second portion of the second ground plane; and removing the second photoresist coating. In another aspect, the metal oxide comprises aluminum oxide. In another aspect, forming the capacitor comprises depositing a metal oxide on a top of the capacitor electrode, and depositing the metal on a top of the metal oxide. In another aspect, the capacitor electrode comprises a first capacitor electrode separated from a second capacitor electrode by a fourth gap and forming the capacitor comprises: (1) depositing a metal oxide on a top of the first capacitor electrode, a side of the first capacitor electrode within the third gap, a top of the second capacitor electrode, and a side of the second capacitor electrode within the third gap, and (2) depositing the metal within a remaining portion of the third gap and a top of the metal oxide over the first capacitor electrode and the second capacitor electrode. In another aspect, the amplifier has one or more performance characteristics comprising: a gain of about 15-25 dB; a bandwidth of about 500 MHz bandwith; a tunable amplification band center; or a noise temperature near the quantum limit within the bandwidth.

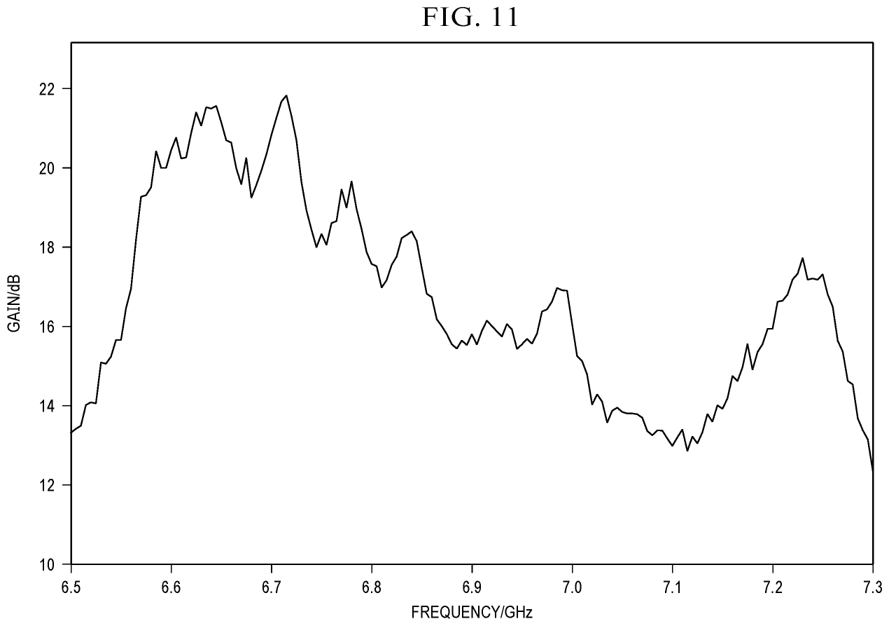

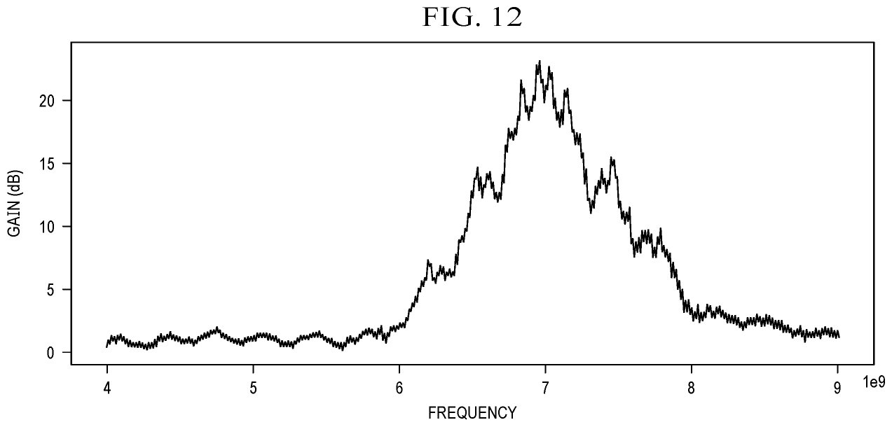

FIGS. 10-12 are graphs show various performance characteristics of the wide-band Josephson parametric amplifier in accordance with embodiments of the present disclosure. More specifically, FIG. 10 is a graph of the system noise temperature of the wide-band Josephson parametric amplifier compared to the quantum noise limit in accordance with another embodiment of the present disclosure. The measured noise temperature shows that the wide-band Josephson parametric amplifier reached or was near the so-called quantum noise limit, which is the minimal noise level (best noise performance allowed by physics) for any amplifier in the frequency band. FIG. 11 is a graph of the signal gain versus frequency of the wide-band Josephson parametric amplifier compared to the quantum noise limit in accordance with another embodiment of the present disclosure. FIG. 12 is a graph of the real gain versus frequency of the wide-band Josephson parametric amplifier compared to the quantum noise limit in accordance with another embodiment of the present disclosure.

In addition, the performance of one embodiment of the wide-band Josephson parametric amplifier in accordance with the present disclosure was tested and detailed in B. Qing, L. Nguyen, X. Liu, H. Ren, W. Livingston, N. Goss, A. Hajr, T. Chistolini, Z. Pedramrazi, D. Santiago, J. Luo, I. Siddigi, “Broadband CPW-based impedance-transformed Josephson parameter amplifier”, arXiv:2310.17084v1 [quant-ph] 26 Oct 2023. More specifically, the foregoing article stated “Notably, the CIMPA [CPW-based broadband impedance-transformed parametric amplifier] performs as well as the other IMPAs [broadband impedance-transformed Josephson parametric amplifier] despite such simplicity. The amplifier displays an instantaneous bandwidth of 700 (200) MHz for 15 (20) dB gain, a 1.4 GHz flux-tunable bandwidth, a saturation input power of approximately —110 dBm, and no significant back action on the qubit.” (pages 1-2). In addition, the foregoing article stated that “it fills the technological gap between JPAs [Josephson parametric amplifiers] and TWPAs [traveling-wave-parametric-amplifier], with potential applications ranging from qubit readout to axion dark matter detection.” (page 5).

Circuits can be implemented with, but are not limited to, single or combinations of discrete electrical and electronic components, integrated circuits, semiconductor devices, analog devices, digital devices, etc. Elements can be coupled together using any type of suitable direct or indirect connection between the elements including, but not limited to, wires, pathways, channels, vias, electromagnetic induction, electrostatic charges, optical links, wireless communication links, etc.

It will be understood that particular embodiments described herein are shown by way of illustration and not as limitations of the invention. The principal features of this invention can be employed in various embodiments without departing from the scope of the invention. Those skilled in the art will recognize, or be able to ascertain using no more than routine experimentation, numerous equivalents to the specific procedures described herein. Such equivalents are considered to be within the scope of this invention and are covered by the claims.

All publications and patent applications mentioned in the specification are indicative of the level of skill of those skilled in the art to which this invention pertains. All publications and patent applications are herein incorporated by reference to the same extent as if each individual publication or patent application was specifically and individually indicated to be incorporated by reference.

In the specification, reference may be made to the spatial relationships between various components and to the spatial orientation of various aspects of components as the devices are depicted in the attached drawings. However, as will be recognized by those skilled in the art after a complete reading of the present application, the devices, members, apparatuses, etc. described herein may be positioned in any desired orientation. Thus, the use of terms such as “above,” “below,” “upper,” “lower,” or other like terms to describe a spatial relationship between various components or to describe the spatial orientation of aspects of such components should be understood to describe a relative relationship between the components or a spatial orientation of aspects of such components, respectively, as the device described herein may be oriented in any desired direction.

The use of the word “a” or “an” when used in conjunction with the term “comprising” in the claims and/or the specification may mean “one,” but it is also consistent with the meaning of “one or more,” “at least one,” and “one or more than one.” The use of the term “or” in the claims is used to mean “and/or” unless explicitly indicated to refer to alternatives only or the alternatives are mutually exclusive, although the disclosure supports a definition that refers to only alternatives and “and/or.” Throughout this application, the term “about” is used to indicate that a value includes the inherent variation of error for the device, the method being employed to determine the value, or the variation that exists among the study subjects.

As used in this specification and claim(s), the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps.

In embodiments of any of the compositions and methods provided herein, “comprising” may be replaced with “consisting essentially of” or “consisting of.” As used herein, the phrase “consisting essentially of” requires the specified integer(s) or steps as well as those that do not materially affect the character or function of the claimed invention. As used herein, the term “consisting” is used to indicate the presence of the recited integer (e.g., a feature, an element, a characteristic, a property, a method/process step, or a limitation) or group of integers (e.g., feature(s), element(s), characteristic(s), property(ies), method/process(s) steps, or limitation(s)) only.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, AB, BBC, AAABCCCC, CBBAAA, CABABB, and so forth. The skilled artisan will understand that typically there is no limit on the number of items or terms in any combination, unless otherwise apparent from the context.

As used herein, words of approximation such as, without limitation, “about,” “near,” “substantial” or “substantially” refers to a condition that when so modified is understood to not necessarily be absolute or perfect but would be considered close enough to those of ordinary skill in the art to warrant designating the condition as being present. The extent to which the description may vary will depend on how great a change can be instituted and still have one of ordinary skill in the art recognize the modified feature as still having the required characteristics and capabilities of the unmodified feature. In general, but subject to the preceding discussion, a numerical value herein that is modified by a word of approximation such as “about” may vary from the stated value by at least +1, 2, 3, 4, 5, 6, 7, 10, 12 or 15%.

All of the devices and/or methods disclosed and claimed herein can be made and executed without undue experimentation in light of the present disclosure. While the devices and/or methods of this invention have been described in terms of particular embodiments, it will be apparent to those of skill in the art that variations may be applied to the compositions and/or methods and in the steps or in the sequence of steps of the method described herein without departing from the concept, spirit and scope of the invention. All such similar substitutes and modifications apparent to those skilled in the art are deemed to be within the spirit, scope, and concept of the invention as defined by the appended claims.

Furthermore, no limitations are intended to the details of construction or design herein shown, other than as described in the claims below. It is therefore evident that the particular embodiments disclosed above may be altered or modified and all such variations are considered within the scope and spirit of the disclosure. Accordingly, the protection sought herein is as set forth in the claims below.

Modifications, additions, or omissions may be made to the systems and apparatuses described herein without departing from the scope of the invention. The components of the systems and apparatuses may be integrated or separated. Moreover, the operations of the systems and apparatuses may be performed by more, fewer, or other components. The methods may include more, fewer, or other steps. Additionally, steps may be performed in any suitable order.

To aid the Patent Office, and any readers of any patent issued on this application in interpreting the claims appended hereto, applicants wish to note that they do not intend any of the appended claims to invoke 35 U.S.C. § 112(f) as it exists on the date of filing hereof unless the words “means for” or “step for” are explicitly used in the particular claim.

What is claimed is:

1. A wide-band Josephson parametric amplifier comprising:
a substrate;
a coplanar waveguide disposed on the substrate having an impedance that varies over a length of the coplanar waveguide, wherein the coplanar waveguide comprises a conductor separated from a first ground plane by a first gap and a second ground plane by a second gap; and
a nonlinear resonator disposed on the substrate and coupled to the coplanar waveguide.

2. The wide-band Josephson parametric amplifier of claim 1, wherein the nonlinear resonator comprises:
a capacitor disposed on the substrate and coupled to the coplanar waveguide; and
one or more superconducting quantum interface devices disposed on the substrate and coupled to the capacitor.

3. The wide-band Josephson parametric amplifier of claim 2, wherein each superconducting quantum interface device comprises two Josephson junctions in parallel.

4. The wide-band Josephson parametric amplifier of claim 2, wherein the one or more superconducting quantum interface devices comprise two or more one or more superconducting quantum interface devices connected in series.

5. The wide-band Josephson parametric amplifier of claim 1, further comprising:
an input/output port disposed on the substrate and coupled to the coplanar waveguide; and
one or more control ports disposed on the substrate and inductively coupled to the nonlinear resonator.

6. The wide-band Josephson parametric amplifier of claim 1, wherein the conductor, the first ground plane and the second ground plane comprise aluminum.

7. The wide-band Josephson parametric amplifier of claim 1, wherein the impedance of the waveguide is varied by: (1) increasing a width of the conductor over the length of the coplanar waveguide, or (2) coupling a plurality of dielectric bridges to the coplanar waveguide over the length of the coplanar waveguide.

8. The wide-band Josephson parametric amplifier of claim 7, wherein the impedance of the coplanar waveguide varies from about 50 ohms to about 15 ohms.

9. The wide-band Josephson parametric amplifier of claim 7, wherein each dielectric bridge comprises:
a dielectric disposed within the first gap and the second gap, on a top of the first gap and the second gap, the conductor, and extending over a first portion of the first ground plane and a first portion of the second ground plane; and
a metal disposed on a top of the dielectric and extending over a second portion of the first ground plane and a second portion of the second ground plane.

10. The wide-band Josephson parametric amplifier of claim 9, wherein:
the metal comprises aluminum; and
the dielectric comprises aluminum oxide.

11. The wide-band Josephson parametric amplifier of claim 1, wherein the amplifier has one or more performance characteristics comprising:
a gain of about 15-25 dB;
a bandwidth of about 500 MHz bandwidth;
a tunable amplification band center; or
a noise temperature near a quantum limit within the bandwidth.

12. A method of fabricating a wide-band Josephson parametric amplifier comprising:
forming a first ground plane, a second ground plane, a conductor separated from the first ground plane by a first gap and the second ground plane by a second gap, a capacitor electrode, and a first resonator junction lead separated from a second resonator junction lead by a third gap on a substrate, wherein the conductor separated from the first ground plane by the first gap and the second ground plane by the second gap forms a coplanar waveguide;
forming a capacitor on the capacitor electrode;
forming one or more superconducting quantum interface devices by: (1) depositing a metal at a first angle on the substrate wherein a portion of the metal is deposited within a fourth gap next to the first resonator junction lead, (2) oxidizing an exposed portion of the metal deposited within the fourth gap next to the first resonator junction lead, and (3) depositing the metal at a second angle on the substrate within the forth gap next to the second resonator junction lead and overlapping a portion of the oxidized metal next to the first resonator junction lead;
wherein the coplanar waveguide has an impedance that varies over a length of the coplanar waveguide; and
wherein the capacitor is coupled between the coplanar waveguide and the one or more superconducting quantum interface devices.

13. The method of claim 12, wherein the method is performed using a lift-off process, a selective etch process, or a combination thereof.

14. The method of claim 12, wherein:
the first angle comprises about 30 to 45 degrees; and
the second angle comprises about −30 to −45 degrees.

15. The method of claim 12, wherein:
the first angle comprises about 31.5 degrees; and
the second angle comprises about −31.5 degrees.

16. The method of claim 12, wherein the one or more superconducting quantum interface devices are formed before the capacitor is formed.

17. The method of claim 12, wherein the one or more superconducting quantum interface devices comprise two or more superconducting quantum interface devices connected in series.

18. The method of claim 12, wherein each superconducting quantum interface device comprises two Josephson junctions in parallel.

19. The method of claim 12, wherein the one or more superconducting quantum interface devices comprise two or more one or more superconducting quantum interface devices connected in series.

20. The method of claim 12, further comprising:
forming an input/output port disposed on the substrate and coupled to the coplanar waveguide; and
forming one or more control ports disposed on the substrate that are inductively coupled to the one or more superconducting quantum interface devices.

21. The method of claim 12, wherein the conductor, the first ground plane and the second ground plane comprise aluminum.

22. The method of claim 12, wherein the impedance of the waveguide is varied by: (1) increasing a width of the conductor over the length of the coplanar waveguide, or (2) coupling a plurality of dielectric bridges to the coplanar waveguide over the length of the coplanar waveguide.

23. The method of claim 22, wherein the impedance of the coplanar waveguide varies from about 50 ohms to about 15 ohms.

24. The method of claim 22, further comprising forming the plurality of dielectric bridges by:
depositing a first photoresist coating;
exposing the first photoresist coating in accordance with a first pattern;
depositing a metal oxide according to the first pattern: (1) within the first gap and the second gap, (2) on a top of the first gap, the conductor and the second gap, and (3) extending over a first portion of the first ground plane and a first portion of the second ground plane;
removing the first photoresist coating;
depositing a second photoresist coating;
exposing the first photoresist coating in accordance with a second pattern;
depositing the metal on a top of the metal oxide and extending over a second portion of the first ground plane and a second portion of the second ground plane; and
removing the second photoresist coating.

25. The method of claim 24, wherein the metal oxide comprises aluminum oxide.

26. The method of claim 12, wherein forming the capacitor comprises:
depositing a metal oxide on a top of the capacitor electrode; and
depositing the metal on a top of the metal oxide.

27. The method of claim 12, wherein:
the capacitor electrode comprises a first capacitor electrode separated from a second capacitor electrode by a fourth gap; and
forming the capacitor comprises: (1) depositing a metal oxide on a top of the first capacitor electrode, a side of the first capacitor electrode within the third gap, a top of the second capacitor electrode, and a side of the second capacitor electrode within the third gap, and (2) depositing the metal within a remaining portion of the third gap and a top of the metal oxide over the first capacitor electrode and the second capacitor electrode.

28. The method of claim 12, wherein the amplifier has one or more performance characteristics comprising:
a gain of about 15-25 dB;
a bandwidth of about 500 MHz bandwidth;
a tunable amplification band center; or
a noise temperature near a quantum limit within the bandwidth.

29. A wide-band Josephson parametric amplifier fabricated in accordance with the method of claim 12.
